(19) United States
(12) Patent Application Publication
(10) Pub. No.: US 2007/0151712 A1
(43) Pub. Date: Jul. 5, 2007

(54) Heat sink for distributing a thermal load

(76) Inventors: Jimmy G. Foster SR., Morrisville, NC (US); Donna C. Hardee, Raleigh, NC (US); Don S. Keener, Apex, NC (US); Robert R. Wolford, Raleigh, NC (US)

Correspondence Address: IBM (RPS-BLF);c/o BIGGERS & OHANIAN, LLP, P.O. BOX 1469, AUSTIN, TX, 78767-1469, US

(21) Appl. No.: 11/326,566

(22) Filed: Jan. 5, 2006

(51) Int. Cl. H05K 7/20

(52) U.S. Cl. 165/104.33; 361/700; 257/715; 361/697; 165/80.4

(57) ABSTRACT

A heat sink for distributing a thermal load is disclosed that includes a base receiving the thermal load, the base having a front surface, a back surface, an inner surface, and an outer surface, the outer surface shaped generally as a cylinder and having a flat mounting region, and the inner surface shaped as a cylinder so as to define a cylindrical receiving space, a cylindrical thermal transport connected to the inner surface of the base so as to distribute the thermal load along the inner surface of the base, and heat-dissipating fins connected to the cylindrical thermal transport and extending from the cylindrical thermal transport towards a central axis of the cylindrical receiving space.

### BACKGROUND OF THE INVENTION

1. Field of the Invention

The field of the invention is heat sinks for distributing a thermal load.

2. Description Of Related Art

The development of the EDVAC computer system of 1948 is often cited as the beginning of the computer era. Since that time, users have relied on computer systems to simplify the process of information management. Today's computer systems are much more sophisticated than early systems such as the EDVAC. Such modern computer systems deliver powerful computing resources to provide a wide range of information management capabilities through the use of computer software such as database management systems, word processors, spreadsheets, client/server applications, web services, and so on.

In order to deliver powerful computing resources, computer system designers must design powerful computer processors. Current computer processors, for example, are capable of executing billions of computer program instructions per second. Operating these computer processors requires a significant amount of power, and often such processors can consume over 100 watts. Consuming significant amounts of power generates a considerable amount of heat. Unless the heat is removed, heat generated by a computer processor may degrade or destroy the processor's functionality.

To prevent the degradation or destruction of a computer processor, a computer architect may remove heat from the processor by using heat sinks, fans, heat pipes, or even refrigeration systems. Current heat sinks, however, only provide one or two cooling surfaces with attached fins for dissipating the heat absorbed by the heat sinks. Such heat sinks are often unable to remove the heat necessary to prevent damage to today's computer processors because physical limitations may prevent a system designer from designing cooling surface large enough or fins tall enough to dissipate the required amount of heat from the processor. Combining a fan with a heat sink may improve the ability to remove heat from the computer processor, but such a combination also may not be sufficient prevent damage to today's computer processors. Heat pipes attached to a computer processor are capable of removing large quantities of heat from the computer processor, but heat pipes may not be an option where a system designer requires a local cooling solution. Refrigeration systems also effectively remove heat, but such systems are typically large and expensive.

### SUMMARY OF THE INVENTION

A heat sink for distributing a thermal load is disclosed that includes a base receiving the thermal load, the base having a front surface, a back surface, an inner surface, and an outer surface, the outer surface shaped generally as a cylinder and having a flat mounting region, and the inner surface shaped as a cylinder so as to define a cylindrical receiving space, a cylindrical thermal transport connected to the inner surface of the base so as to distribute the thermal load along the inner surface of the base, and heat-dissipating fins connected to the cylindrical thermal transport and extending from the cylindrical thermal transport towards a central axis of the cylindrical receiving space.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a perspective view of an exemplary heat sink for distributing a thermal load according to embodiments of the present invention.

FIG. 2 sets forth a perspective view of a further exemplary heat sink for distributing a thermal load according to embodiments of the present invention.

FIG. 3 sets forth a front view of a further exemplary heat sink for distributing a thermal load according to embodiments of the present invention.

FIG. 4 sets forth a front view of a further exemplary heat sink for distributing a thermal load according to embodiments of the present invention.

### DETAILED DESCRIPTION OF EXEMPLARY EMBODIMENTS

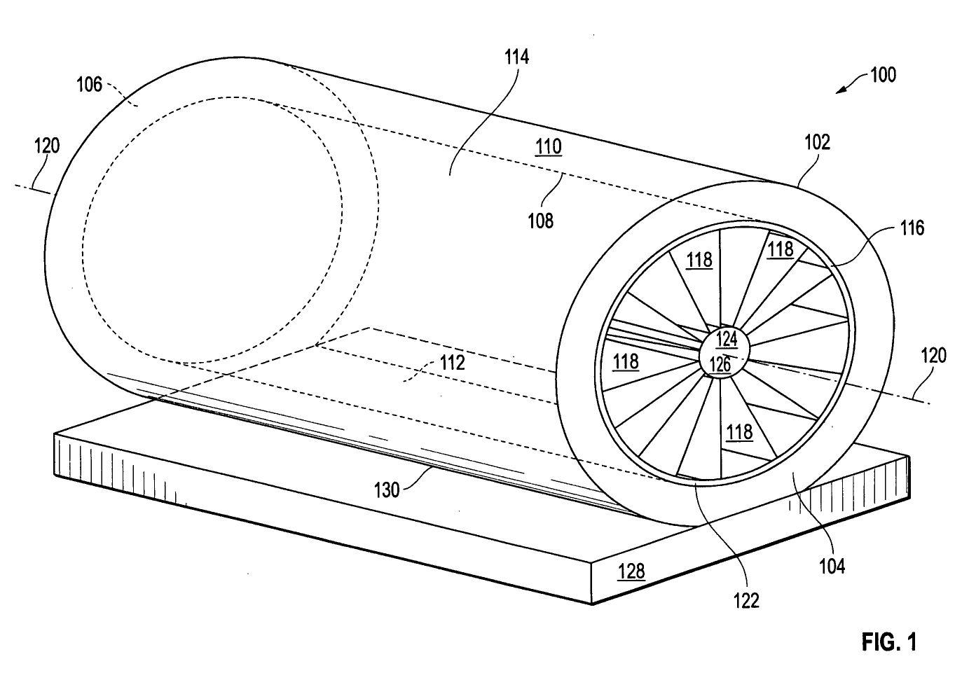

Exemplary heat sinks for distributing a thermal load according to embodiments of the present invention are described with reference to the accompanying drawings, beginning with FIG. 1. FIG. 1 sets forth a perspective view of an exemplary heat sink (100) for distributing a thermal load according to embodiments of the present invention. The thermal load is the rate of thermal energy produced over time from the operation of an integrated circuit package (128) such as, for example, a computer processor or memory chip. A measure of thermal load is typically expressed in units of Watts.

In the example of FIG. 1, the heat sink (100) is a thermal conductor configured to absorb and dissipate the thermal load from the integrated circuit package (128) thermally connected with the heat sink (100). Thermal conductors used in designing the heat sink (100) may include, for example, aluminum, copper, silver, aluminum silicon carbide, or carbon-based composites. Heat sink (100) absorbs the thermal load from the integrated circuit package through thermal conduction. When thermally connecting the heat sink (100) to the integrated circuit package (128), the heat sink provides additional thermal mass, cooler than the integrated circuit package (128), into which the thermal load may flow. After absorbing the thermal load, the heat sink (100) dissipates the thermal load through thermal convection and thermal radiation into the air surrounding the heat sink (100). Increasing the surface area of the heat sink (100) typically increases the rate of dissipating the thermal load. The surface area of the heat sink (100) may be increased by enlarging the base of the heat sink or increasing the number of heat-dissipating fins.

The example heat sink (100) of FIG. 1 includes a base (102). The base (102) receives a thermal load from integrated circuit (128). The base has a front surface (104), a back surface (106), an inner surface (108), and an outer surface (110). The outer surface (110) is shaped generally as a cylinder and has a flat mounting region (112). The inner surface (108) is shaped as a cylinder so as to define a cylindrical receiving space (114). In the example of FIG. 1, the front surface (104) is parallel to the back surface (106). The front surface (104) and the back surface (106) are perpendicular to a line intersecting the centers of the front surface (104) and the back surface (106).

In the example of FIG. 1, the inner surface (108) of the base (102) may be created by boring a hollowed region through the base (102) along an axis (120) shifted upward so as to be off-centered from the central axis (not shown) of the base (102). The hollowed region extends from the front surface (104) to the back surface (106) such that the central axis (120) of the hollowed region is perpendicular to the front surface (104) and the back surface (106). The walls of the hollowed region form the inner surface (108). The inner surface (108) is shaped as a cylinder so as to define a cylindrical receiving space (114) for receiving a cylindrical thermal transport (116), heat-dissipating fins (118), and an axial thermal transport (124).

In the example of FIG. 1, the flat mounting region (112) is formed from a rounded portion of the outer surface (110) by milling a rounded portion of the outer surface (110) flat. The flat mounting region (112) of the outer surface (110) connects to the integrated circuit package (128) by a thermal interface (130). The thermal interface (130) is a thermally conductive material that reduces the thermal resistance associated with transferring the thermal load from the integrated circuit package (128) to the heat sink (100). The thermal interface (130) between the integrated circuit package (128) and the heat sink (100) has less thermal resistance than could typically be produced by connecting the integrated circuit package (128) directly to the heat sink (100). Decreasing the thermal resistance between the integrated circuit package (128) and the heat sink (100) increases the efficiency of transferring the thermal load from the integrated circuit package (128) to the heat sink (100). The thermal interface (130) in the example of FIG. 1 may include non-adhesive materials such as, for example, thermal greases, phase change materials, and gap-filling pads. The thermal interface (130) may also include adhesive materials such as, for example, thermosetting liquids, pressure-sensitive adhesive (‘PSA’) tapes, and thermoplastic or thermosetting bonding films.

The example heat sink (100) of FIG. 1 also includes a cylindrical thermal transport (116) connected to the inner surface (108) of the base (102) so as to distribute the thermal load along the inner surface (108) of the base (102). The cylindrical thermal transport (116) is a heat transfer mechanism that transports thermal energy from one region along the cylindrical thermal transport (116) to another region along the cylindrical thermal transport (116) with a minimal loss of thermal energy. Such cylindrical thermal transports have an efficiency that approximates a closed thermal transfer system. Examples of cylindrical thermal transports include heat pipes and carbon nanotubes.

In the example of FIG. 1, the cylindrical thermal transport (116) is implemented as a flat heat pipe (122) configured as a cylindrical tube. A heat pipe is a closed evaporator-condenser system consisting of a sealed, hollow tube or a sealed, flat, hollow plate whose inside walls are lined with a capillary structure, also referred to as a ‘wick.’ A thermodynamic working fluid having substantial vapor pressure at the desired operating temperature saturates the pores of the wick. The fluid heats and evaporates when heat is applied to a region of the heat pipe. As the evaporating fluid fills the hollow center of the wick, the vapor diffuses throughout the heat pipe. The vapor condenses in the heat pipe wherever the temperature along the heat pipe falls below the temperature of the evaporation area. As the vapor condenses, the vapor gives up the heat the vapor acquired during evaporation. Capillary action within the wick returns the condensate to the evaporation area and completes the operating cycle. In the example of FIG. 1, the flat heat pipe (122) is implemented as a relatively thin lining along the inner surface (108) of the base (102). The thickness of typical flat heat pipes useful in heat sinks according to embodiments of the present invention may range from approximately 1.2 millimeters to 2.0 millimeters in thickness. Such a range of thickness is for example only and not for limitation. Other thicknesses as will occur to those of skill in the art may be useful in heat sinks for distributing a thermal load according to embodiments of the present invention. The flat heat pipe (122) in the example of FIG. 1 is bent to form a cylindrical tube with a diameter that conforms to the diameter of the receiving space (114). The flat heat pipe (122) extends in length from the front surface (104) of the base (102) to the back surface (106) of the base (102). The flat heat pipe (122) connects to the inner surface (108) by a press-fit connection. Such a press-fit connection is for example only, and not for limitation. The flat heat pipe (122) may also connect to the inner surface (108) by a fastening mechanism such as, for example, a clip, an adhesive, or a thermal interface.

The example heat sink (100) of FIG. 1 also includes heat-dissipating fins (118) connected to the cylindrical thermal transport (116). The heat-dissipating fins (118) extend from the cylindrical thermal transport (116) towards a central axis (120) of the cylindrical receiving space (114). The heat-dissipating fins (118) are thermal conductors that provide additional surface area to heat sink (100) for dissipating the thermal load. In the example of FIG. 1, the heat-dissipating fins (118) extend in length from the front surface (104) of the base (102) to the back surface (106) of the base (102). The heat-dissipating fins (118) extend in height from the inner surface of the cylindrical thermal transport (116) for a distance that provides the capability of inserting an axial thermal transport (124) into the receiving space (114) along the central axis (120) of the receiving space (114). The heat-dissipating fins (118) connect to the cylindrical thermal transport (116) by a press-fit connection. Such a press-fit connection is for example only, and not for limitation. The heat-dissipating fins (118) may also connect to the cylindrical thermal transport (116) by a fastening mechanism such as, for example, a clip, an adhesive or a thermal interface. The number of heat-dissipating fins (118) in the example of FIG. 1 connected to the cylindrical thermal transport (116) may be limited by the height-to-gap aspect ratio of the fins (118). Typical height-to-gap aspect ratios for the bonded press-fit heat-dissipating fins (118) in the example of FIG. 1 range from 20 to 40. The heat-dissipating fins (118) may be formed by folding a rectangular piece of sheet metal multiple times along opposite sides and shaping the folded sheet metal to as a cylinder for insertion into the receiving space (114). The heat-dissipating fins (118) may also be formed by inserting separate rectangular metal sheets into the receiving space (114) along guides connected to the front surface (104) and the back surface (106).

The example heat sink (100) of FIG. 1 also includes an axial thermal transport (124) extending along the central axis (120) of the cylindrical receiving space (114) and connected to the heat-dissipating fins (118) so as to distribute the thermal load along the heat-dissipating fins (118). The axial thermal transport (124) is a heat transfer mechanism that transports thermal energy from one region along the cylindrical thermal transport to another region along the axial thermal transport (124) with a minimal loss of thermal energy. Such axial thermal transports have an efficiency that approximates a closed thermal transfer system. Examples of axial thermal transports include heat pipes and carbon nanotubes. In the example of FIG. 1, the axial thermal transport (124) is implemented as a heat pipe (126). The heat pipe (126) extends in length from the front surface (104) of the base (102) to the back surface (106) of the base (102). In the example of FIG. 1, the heat pipe (124) connects to the heat-dissipating fins (118) by a press-fit connection. Such a press-fit connection is for example only, and not for limitation. The heat pipe (126) may also connect to the heat-dissipating fins (118) by a fastening mechanism such as, for example, a clip, an adhesive, or a thermal interface.

Although, the axial thermal transport (124) depicted in the example of FIG. 1 connects to the heat-dissipating fins (118), such a depiction is for example and not for limitation. In addition to connecting to the heat-dissipating fins (118), the axial thermal transport (124) may also be connected to cylindrical thermal transport (116) or directly to the integrated circuit package (128). Such additional connections may be implemented in a manner that minimizes the obstruction of airflow through the receiving space (114). For example, the axial thermal transport (124) may connect to the cylindrical thermal transport (116) by displacing or removing one or more of the heat-dissipating fins (118). Displacing or removing one or more of the heat-dissipating fins (118) allows the end of the axial thermal transport (124) to be configured to connect to the inner surface of the cylindrical thermal transport (116). The axial thermal transport (124) may connect to the integrated circuit package (128) by configuring the axial thermal transport (124) to extend beyond the front surface (104) of the base (102) and the back surface (106) of the base (102) and fasten to the flat mounting region (112) adjacent to the integrated circuit package (128).

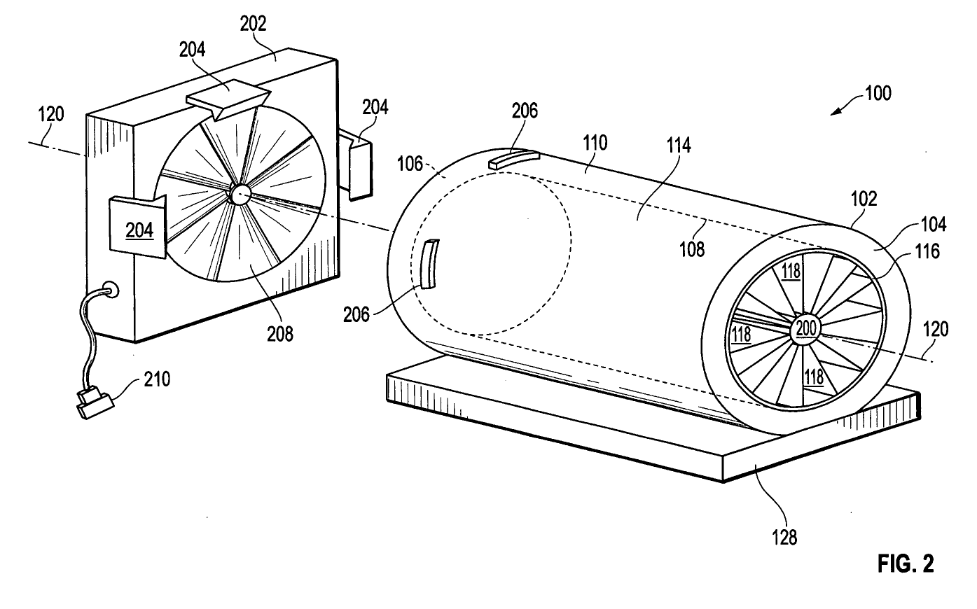

Some heat sinks for distributing a thermal load according to embodiments of the present invention include both a cylindrical thermal transport and an axial thermal transport to distribute the thermal load throughout the heat sink. In other heat sinks for distributing a thermal load according to embodiments of the present invention, the axial thermal transport is replaced with a cylindrical air flow plug that induces the air flow through the cylindrical receiving space (114) across the surface of the heat-dissipating fins (118). For further explanation, therefore, FIG. 2 sets forth a perspective view of a further exemplary heat sink (100) for distributing a thermal load according to embodiments of the present invention.

The example heat sink (100) of FIG. 2 is similar in structure to the example heat sink of FIG. 1. That is, similar to the example of FIG. 1 in that: The example heat sink (100) of FIG. 2 includes a base (102). The base (102) receives a thermal load from integrated circuit (128). The base (102) has a front surface (104), a back surface (106), an inner surface (108), and an outer surface (110). The outer surface (110) is shaped generally as a cylinder and having a flat mounting region. The inner surface (108) is shaped as a cylinder so as to define a cylindrical receiving space (114). The example heat sink (100) of FIG. 2 includes a cylindrical thermal transport (116) connected to the inner surface (108) of the base (102). The cylindrical thermal transport (116) distributes the thermal load along the inner surface (108) of the base (102). The example heat sink (100) of FIG. 2 includes heat-dissipating fins (118) connected to the cylindrical thermal transport (116). The heat-dissipating fins (118) extend from the cylindrical thermal transport (116) towards a central axis (120) of the cylindrical receiving space (114). The outer surface (110) in the example of FIG. 2 connects to an integrated circuit package (128) by a thermal interface so as to receive the thermal load generated by the integrated circuit package (128).

In addition, however, the example heat sink (100) of FIG. 2 also includes a cylindrical air flow plug (200) extending along the central axis (120) of the cylindrical receiving space (114) and connected to the heat-dissipating fins (118). The cylindrical air flow plug (200) extends in length from the front surface (104) of the base (102) to the back surface (106) of the base (102). The diameter of the cylindrical air flow plug (200) conforms to the cylindrical region between the heat-dissipating fins (118) along the central axis (120) of the cylindrical receiving space (114) so as to induce the air flow through the cylindrical receiving space (114) across the surface of the heat-dissipating fins (118).

The example heat sink (100) of FIG. 2 also includes a fan (202) fastened to the base (102) and oriented so as to induce air flow across the heat-dissipating fins (118) along the central axis (120) of the cylindrical receiving space (114). In the example of FIG. 2, the fan (202) connects to the base (102) by clips (204) mounted on the sides of fan (202). The clips (204) engage detents (206) mounted on the outer surface (110) of the base (102). The depiction of the fan (202) connected to the base (102) by clips (204) and detents (206) in the example of FIG. 2 is for explanation and not for limitation. In fact, the fan (202) need not connect to the base (102) at all. The fan (202) may mount to a circuit board adjacent to the base (102) such that the fan (202) is oriented with respect to the base (102) so as to induce air flow across the heat-dissipating fins (118) along the central axis (120) of the cylindrical receiving space (114). In the example of FIG. 2, readers will notice that the housing of the fan (202) is shaped as a rectangular box. The housing depicted in the example of FIG. 2 shaped as a rectangular box is for explanation only, and not for limitation. In fact, the housing of the fan (202) may also be shaped as a cylinder, an octagon, a hexagon, or other shapes as will occur to those of skill in the art.

The fan (202) in the example of FIG. 2 induces air flow across the heat-dissipating fins (118) along the central axis (120) of the cylindrical receiving space (114) by rotating fan blades (208). The fan blades (208) rotate under the power of a fan motor (not shown) that converts electrical energy to mechanical energy. The fan motor receives electrical energy from a power supply through electrical plug (210). The fan motor transmits power to the fan blades (208) through a shaft (not shown) connected with the fan blades (208) and the fan motor.

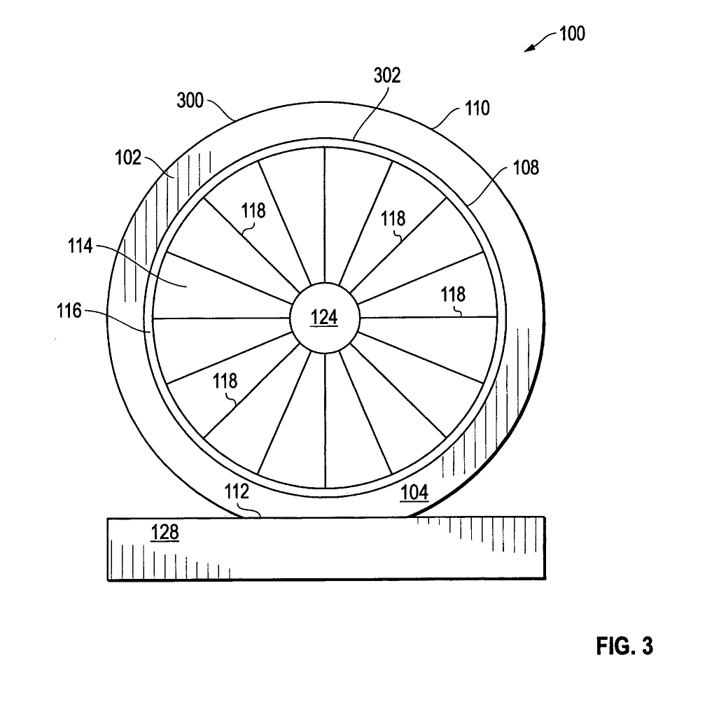

Readers will notice that the example heat sinks of FIG. 1 and of FIG. 2 are generally circular in cross section. For further explanation of a heat sink generally circular in cross section, FIG. 3 sets forth a front view of a further exemplary heat sink (100) for distributing a thermal load according to embodiments of the present invention. The example heat sink (100) of FIG. 3 is similar in structure to the example heat sink of FIG. 1. That is, similar to the example of FIG. 1 in that: The example heat sink (100) of FIG. 3 includes a base (102). The base (102) receives a thermal load from an integrated circuit package (128). The base (102) has a front surface (104), a back surface (not shown), an inner surface (108), and an outer surface (110). The outer surface (110) is shaped generally as a cylinder and has a flat mounting region (112). The inner surface (108) is shaped as a cylinder so as to define a cylindrical receiving space (114). The example heat sink (100) of FIG. 3 includes a cylindrical thermal transport (116) connected to the inner surface (108) of the base (102) so as to distribute the thermal load along the inner surface (108) of the base (102). The example heat sink (100) of FIG. 3 includes heat-dissipating fins (118) connected to the cylindrical thermal transport (116). The heat-dissipating fins (118) extend from the cylindrical thermal transport (116) towards a central axis (not shown) of the cylindrical receiving space (114). The example heat sink (100) includes an axial thermal transport (124) extending along the central axis (not shown) of the cylindrical receiving space (114). The axial thermal transport (124) connects to the heat-dissipating fins (118) so as to distribute the thermal load along the heat-dissipating fins (118). The flat mounting region (112) in the example of FIG. 3 connects to an integrated circuit package (128) by a thermal interface so as to receive the thermal load generated by the integrated circuit package (128).

In addition, the outer surface (110) of the heat sink is shaped generally as a circular cylinder. A circular cylinder is a term of art describing a cylinder with a circular cross section. The flat mounting region (112) of the outer surface (110) is flattened at where the outer surface (110) intersects with the integrated circuit package (128), but otherwise the outer surface (110) is shaped generally as a circular cylinder. The bases of a circular cylinder therefore are circles. In the example of FIG. 3, the bases of the circular cylinder generally defined by the outer surface (110) are defined by the front outer edge (300) and the back outer edge (not shown). The front outer edge (300) is the edge formed by the intersection of the front surface (104) and the outer surface (110). The back outer edge is the edge formed by the intersection of the back surface (not shown) and the outer surface (110). The line connecting the centers of the bases defined by the front outer edge (300) and the back outer edge is perpendicular to the bases defined by the front outer edge (300) and the back outer edge. In the example of FIG. 3, the front outer edge (300) and the back outer edge are shaped generally as circles.

In the example of FIG. 3, the inner surface (108) is shaped as a circular cylinder. In the example of FIG. 3, the bases of the circular cylinder generally defined by the inner surface (108) are defined by the front inner edge (302) and the back inner edge (not shown). The front inner edge (302) is the edge formed by the intersection of the front surface (104) and the inner surface (108). The back inner edge is the edge formed by the intersection of the back surface (not shown) and the inner surface (108). The line connecting the centers of the bases defined by the front inner edge (302) and the back inner edge is perpendicular to the bases defined by the front inner edge (302) and the back inner edge. In the example of FIG. 3, the front inner edge (302) and the back inner edge are shaped as circles.

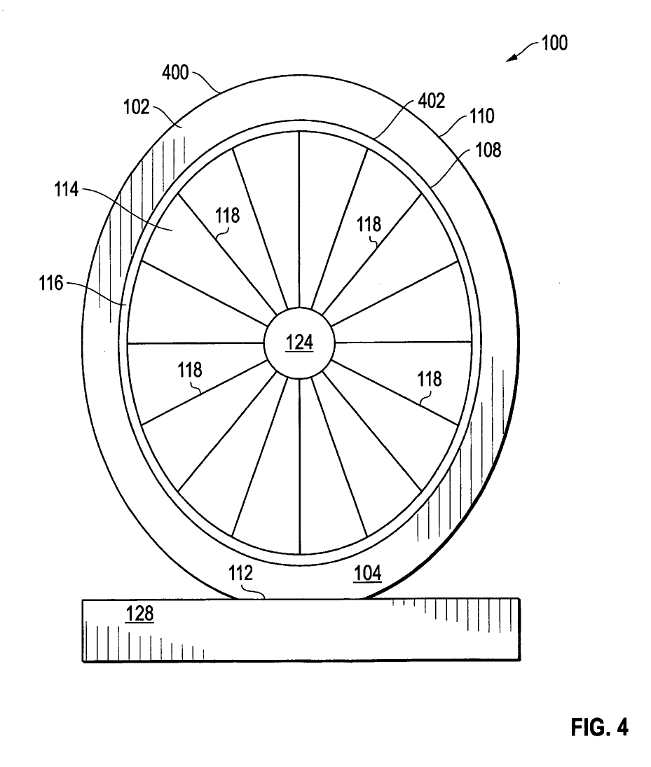

Although the example heat sinks in FIGS. 1, 2, and 3 are generally circular in cross section, not all heat sinks for distributing a thermal load according to embodiments of the present invention are circular in cross section. For further explanation of a heat sink generally elliptical in cross section, FIG. 4 sets forth a front view of a further exemplary heat sink (100) for distributing a thermal load according to embodiments of the present invention. The example heat sink (100) of FIG. 4 is similar in structure to the example heat sink of FIG. 1. That is, similar to the example of FIG. 1 in that: The example heat sink (100) of FIG. 4 includes a base (102). The base (102) receives a thermal load from an integrated circuit (128). The base (102) has a front surface (104), a back surface (not shown), an inner surface (108), and an outer surface (110). The outer surface (110) is shaped generally as a cylinder and has a flat mounting region (112). The inner surface (108) is shaped as a cylinder so as to define a cylindrical receiving space (114). The example heat sink (100) of FIG. 4 includes a cylindrical thermal transport (116) connected to the inner surface (108) of the base (102). The cylindrical thermal transport (116) distributes the thermal load along the inner surface (108) of the base (102). The example heat sink (100) of FIG. 4 includes heat-dissipating fins (118) connected to the cylindrical thermal transport (116). The heat-dissipating fins (118) extend from the cylindrical thermal transport (116) towards a central axis (not shown) of the cylindrical receiving space (114). The example heat sink (100) of FIG. 4 includes an axial thermal transport (124) that extends along the central axis (not shown) of the cylindrical receiving space (114). The axial thermal transport (124) connects to the heat-dissipating fins (118) so as to distribute the thermal load along the heat-dissipating fins (118). The flat mounting region (112) in the example of FIG. 4 connects to an integrated circuit package (128) by a thermal interface so as to receive the thermal load generated by the integrated circuit package (128).

In the example of FIG. 4, the outer surface (110) is shaped generally as an elliptical cylinder. An elliptical cylinder is a term of art describing a cylinder with an elliptical cross section. The flat mounting region (112) of the outer surface (110) is flattened at where the outer surface (110) intersects with the integrated circuit package (128), but otherwise the outer surface (110) is shaped generally as an elliptical cylinder. The bases of an elliptical cylinder therefore are ellipses. In the example of FIG. 4, the bases of the elliptical cylinder generally defined by the outer surface (110) are defined by the front outer edge (400) and the back outer edge (not shown). The front outer edge (400) is the edge formed by the intersection of the front surface (104) and the outer surface (110). The back outer edge is the edge formed by the intersection of the back surface (not shown) and the outer surface (110). The line connecting the centers of the bases defined by the front outer edge (400) and the back outer edge is perpendicular to the bases defined by the front outer edge (400) and the back outer edge. In the example of FIG. 4, the front outer edge (400) and the back outer edge are shaped generally as ellipses.

In the example of FIG. 4, the inner surface (108) is shaped as an elliptical cylinder. In the example of FIG. 4, the bases of the elliptical cylinder generally defined by the inner surface (108) are defined by the front inner edge (402) and the back inner edge (not shown). The front inner edge (402) is the edge formed by the intersection of the front surface (104) and the inner surface (108). The back inner edge is the edge formed by the intersection of the back surface (not shown) and the inner surface (108). The line connecting the centers of the bases defined by the front inner edge (402) and the back inner edge is perpendicular to the bases defined by the front inner edge (402) and the back inner edge. In the example of FIG. 4, the front inner edge (402) and the back inner edge are shaped as ellipses.

In view of the explanations set forth above in this specification, readers will recognize that the benefits of distributing a thermal load in a heat sink according to embodiments of the present invention include the fact that heat sinks generally circular in cross section advantageously distribute a thermal load when an enclosure containing the heat sink is also generally circular in cross section and is of similar or larger dimensions.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A heat sink for distributing a thermal load, the heat sink comprising:
a base receiving the thermal load, the base having a front surface, a back surface, an inner surface, and an outer surface, the outer surface shaped generally as a cylinder and having a flat mounting region, and the inner surface shaped as a cylinder so as to define a cylindrical receiving space;
a cylindrical thermal transport connected to the inner surface of the base so as to distribute the thermal load along the inner surface of the base; and
heat-dissipating fins connected to the cylindrical thermal transport and extending from the cylindrical thermal transport towards a central axis of the cylindrical receiving space.

2. The heat sink of claim 1 wherein the cylindrical thermal transport is a flat heat pipe configured as a cylindrical tube.

3. The heat sink of claim 1 further comprising an axial thermal transport extending along the central axis of the cylindrical receiving space and connected to the heat-dissipating fins so as to distribute the thermal load along the heat-dissipating fins.

4. The heat sink of claim 3 wherein the axial thermal transport is a heat pipe.

5. The heat sink of claim 1 further comprising:
a cylindrical air flow plug extending along the central axis of the cylindrical receiving space and connected to the heat-dissipating fins; and
a fan fastened to the base and oriented so as to induce air flow across the heat-dissipating fins along the central axis of the cylindrical receiving space.

6. The heat sink of claim 1 wherein:
the outer surface is shaped generally as a circular cylinder; and
the inner surface is shaped as a circular cylinder.

7. The heat sink of claim 1 wherein:
the outer surface is shaped generally as an elliptical cylinder; and
the inner surface is shaped as an elliptical cylinder.
